(19) United States
(12) Patent Application Publication
(10) Pub. No.: US 2007/0085196 A1
(43) Pub. Date: Apr. 19, 2007

(54) LIGHT EMITTING DIODE PACKAGE

(75) Inventors: Tung-An Chen, Miao-Li County (TW); Chung-Min Chang, Miao-Li County (TW); Chih-Cheng Huang, Miao-Li County (TW); Liang-Chih Lee, Miao-Li County (TW)

Correspondence Address: J C PATENTS, INC., 4 VENTURE, SUITE 250, IRVINE, CA, 92618, US

(73) Assignee: CORETRONIC CORPORATION, Hsinchu (TW)

(21) Appl. No.: 11/465,306

(22) Filed: Aug. 17, 2006

(30) Foreign Application Priority Data
Oct. 18, 2005 (TW) 94136287

(51) Int. Cl. H01L 23/34

(52) U.S. Cl. 257/712

(57) ABSTRACT

A light emitting diode (LED) package is provided. The LED package comprises a first lead, a second lead, a heat dissipater, a housing, a conductor and an LED chip. The dissipater is disposed between the first lead and the second lead. The housing covers the heat dissipater and parts of the first lead and the second lead. The housing has an upper surface that exposes the heat dissipater, the first lead and the second lead. The conductor is connected between the first lead and the heat dissipater. The LED chip further has a first surface and a second surface, which are oppositely disposed, wherein the second surface is disposed on the heat dissipater. The Led chip is electrically connected to the first lead and the second lead.

### CROSS-REFERENCE TO RELATED APPLICATION

This application claims the priority benefit of Taiwan application serial no. 94136287, filed on Oct. 18, 2005. All disclosure of the Taiwan application is incorporated herein by reference.

### BACKGROUND OF THE INVENTION

1. Field of the Invention

The present invention relates to a package structure of a light emitting device, and particularly to a light emitting diode (LED) package.

2. Description of Related Art

Recently, as the LEDs gradually promote the light emitting efficiency, they replace fluorescent lamps and incandescent lamps in some fields, including highly responsive scanner lamps and backlight sources for liquid crystal displays (LCDs).

Referring to FIG. 1, it shows a schematic cross-sectional view of a conventional LED package. As illustrated in FIG. 1, the LED package 100 comprises a housing 102, a packaging gel 104, an LED chip 106 and two bonding wires 108a and 108b. The housing 102 comprises two leads 102a, 102b and a chip supporter 102c disposed on the lead 102. The LED chip 106 is bonded on the chip supporter 102c, and is electrically connected to the two leads 102a and 102b via the two bonding wires 108a, 108b. In more detail, the LED chip 106 has two contact pads 106a, 106b, while the bonding wires 108a, 108b are electrically connected to the contact pads 106a, 106b of the LED chip 160. The package gel 104 encompasses the bonding wires 108a, 108b, the LED chip 106 and parts of the leads 102a, 102b.

It is noted that the LED package 100 is only adapted for LED chips (such as, blue light LED chips, green light LED chips) with two contact pads 106a, 106b disposed on a same surface thereof. However, red light LED chips with two contact pads 106a, 106b disposed on two opposite surfaces thereof, are not adapted for such a structure.

Moreover, in the conventional LED package 100, the chip supporter 102c usually has poor heat dispersion. Therefore, when driven by a higher current, the LED chip 106 is likely to be overheated and damaged because the heat generated by LED chip 106 can not be efficiently dissipated.

### SUMMARY OF THE INVENTION

An object of the invention is to provide an LED package, adapted for red light LEDs, green light LEDs, blue light LEDs, and preventing the LED from being overheated and damaged.

For achieving the foregoing object, the invention provides an LED package. The LED package comprises a first lead, a second lead, a heat dissipater, a housing, a conductor and an LED chip. The heat dissipater is disposed between the first lead and the second lead. The housing covers the heat dissipater and parts of the first lead and the second lead. The housing has an upper surface that exposes the heat dissipater, the first lead and the second lead. The conductor is connected between the first lead and the heat dissipater. The LED chip further has a first surface and a second surface, which are oppositely disposed, wherein the second surface is disposed on the heat dissipater. The Led chip is electrically connected to the first lead and the second lead.

According to an embodiment of the invention, the foregoing LED chip, for example, comprises a first contact pad and a second contact pad, disposed on the first surface of the LED chip. The LED chip is electrically connected to the first lead and the second lead respectively via the first contact pads and the second contact pad. The LED package further comprises two bonding wires, which are connected between the first lead and the first contact pads, and between the second lead and the second contact pad.

According to another embodiment of the invention, the foregoing LED chip, for example, further comprises a first contact pad and a second contact pad, disposed on the second surface and the first surface of the LED chip, respectively. The LED chip is electrically connected to the first lead and the second lead respectively through the first contact pad and the second contact pad. The LED package further comprises a bonding wire, connected between the second contact pad and the second lead.

According to a further embodiment of the invention, the foregoing LED package, for example, further comprises a submount, disposed between the LED chip and the heat dissipater. The LED chip is electrically connected to the first lead and the second lead via the submount. Additionally, the LED package, for example, further comprises a plurality of protrusions, connected between the LED chip and the submount. The LED package, for example, further comprises two bonding wires, one of which is connected between the submount and the first lead and another is connected between the submount and the second lead.

The foregoing conductor, for example, is silver gel.

The foregoing housing, for example, has a recess configured on the first surface of the housing, which exposes the heat dissipater. Moreover, the LED chip is disposed on the heat dissipater in the recess.

The heat dissipater, for example, is a heat sink.

The foregoing heat dissipater, for example, comprises a heat sink, and a heat spread plate disposed between the heat sink and the LED chip.

The foregoing heat dissipater, for example, further comprises a lens, disposed on the upper surface of the housing and covering the LED chip. Additionally, the upper surface of the housing, for example, comprises a slot and the lens, for example, comprises an adapted to be engaged with the slot. The upper surface of the housing, for example, further comprises a positioning slot adjacent to the slot, and the lens, for example, further has a positioning protrusion, disposed on the engaging portion and adapted to be engaged into the positioning slot.

The foregoing housing, for example, has a lower surface opposite to the upper surface, exposing a surface of the heat dissipater, wherein the surface having a profile of round shape with a side cut.

The foregoing LED package, for example, further comprises a protection layer, disposed on the LED chip.

According to the LED package of the invention, since the conductor is connected between the first lead and the heat dissipater and the first contact pad of the LED chip is disposed on a second surface thereof, the first contact pad is electrically connected to the first lead via the heat dissipater and the conductor. Therefore, LED chips including red light LED chips, green light LED chips and blue light LED chips are adapted for the LED package of the present invention.

### BRIEF DESCRIPTION OF THE DRAWING

The features of the invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a schematic cross-sectional view of a conventional LED package.

FIG. 2 is a perspective view of an LED package according to the first embodiment of the invention.

FIG. 3 is a schematic cross-sectional view of the LED package shown in FIG. 2.

FIG. 4 is a perspective view for illustrating a lens of the LED package.

FIG. 5 is a schematic view of the lower surface of the LED package shown in FIG. 2.

FIG. 6 is a perspective view of an LED package according to the second embodiment of the invention.

FIG. 7 is a perspective view of an LED package according to the third embodiment of the invention.

FIG. 8 is schematic cross-sectional view of an LED package according to the fourth embodiment of the invention.

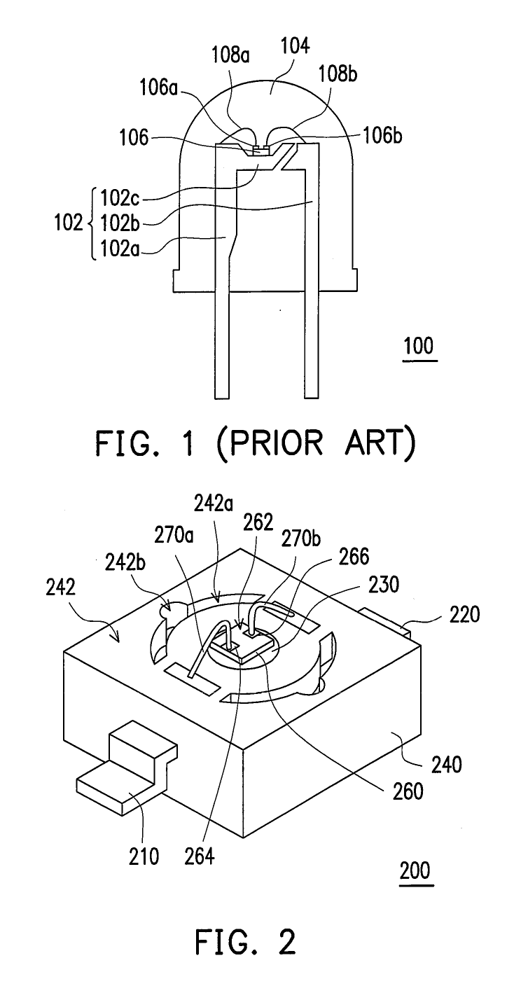

### DESCRIPTION OF THE EMBODIMENTS

In order to make the foregoing objects, features and advantages and others more clearly to be understood, preferred embodiments incorporating with drawings are illustrated as below.

According to an LED package of the invention, two contact pads of an LED chip may be disposed either on a same surface, or on the two opposite surfaces thereof. In other words, the LED chip of the invention can be red light LED chips, green light LED chips or blue light LED chips. The first embodiment and the second embodiment to be illustrated below correspond to LED chips having two contact pads disposed on a same surface. The third embodiment and the fourth embodiment to be illustrated below correspond to LED chips having two contact pads respectively disposed on the opposite two surfaces t thereof. The fourth embodiment also proposes a flip chip bonding technique for the LED package of the invention. The four embodiments according to the invention are now illustrated as below.

### THE FIRST EMBODIMENT

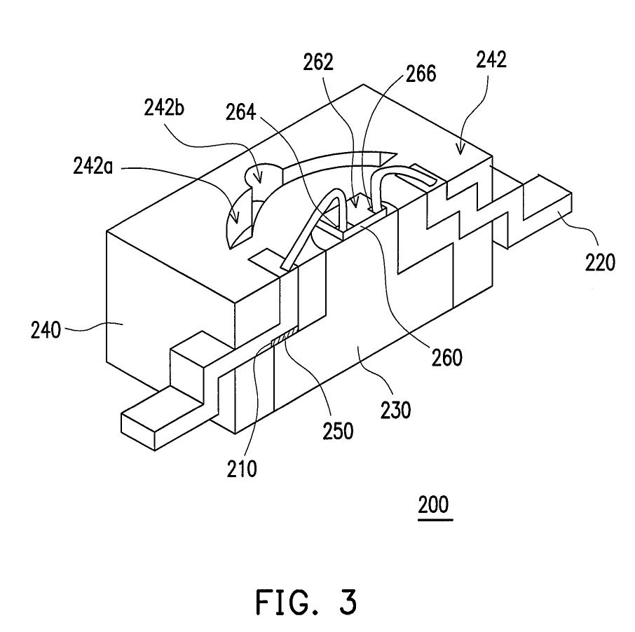

FIG. 2 is a perspective view of an LED package according to the first embodiment of the invention. FIG. 3 is a schematic cross-sectional view of the LED package shown in FIG. 2. Referring to FIGS. 2 and 3, an LED package 200 according to the first embodiment comprises a first lead 210, a second lead 220, a heat dissipater 230, a housing 240, a conductor 250, and an LED chip 260. The heat dissipater 230 is disposed between the first lead 210 and the second lead 220. The housing 240 covers the heat dissipater 230 and parts of the first lead 210 and the second lead 220. The housing 240 has an upper surface 242, exposing the heat dissipater 230 and the firs lead 210, the second lead 220. The conductor 250 is connected between the first lead 210 and the heat dissipater 230. The LED chip 260 comprises a first surface 262 and a second surface (not labeled) opposite to the first surface 262, the second surface being disposed on the heat dissipater 230. The LED chip 260 is electrically connected to the first lead 210 and the second lead 220.

The first lead 210 and the second lead 212 of the foregoing LED package structure 200, for example, are made of a metal material, on a surface of which a metal material such as Ni, Ag, Al, Pt, Pd or Au is coated. The heat dissipater 230, for example, is a heat sink or is composed of a heat sink and a heat spread plate disposed between the heat sink and the LED chip 260. The heat dissipater 230, for example, is made of Ag, Cu, AlN, on a surface of which a metal material such as Ni, Ag, Al, Pt, Pd or Au is coated. The heat spread plate is adapted for decreasing the thermal expansion of the heat dissipater. The material for making the heat spread plate, for example, is, but not limited to, Cu/Mo/Cu or Cu/W/Cu. The housing 240 is made of liquid-crystal polymer (LCP), polyhpthal amide (PPA) or high temperature nylon (HTN).

The LED chip 260, for example, comprises a first contact pad 264 and a second contact pad 266, which are disposed on the first surface 262 of the LED chip 260. The LED chip 260 is electrically connected to the first lead 210 and the second lead 220 respectively via the first contact pad 264 and the second contact pad 266.

According to the first embodiment of the invention, the LED chip 260, for example, is electrically connected to the first lead 210 and the second lead 220 in a way of a bonding wire process. In details, the LED package 200 further comprises two bonding wires 270a and 270b for electrically connecting the LED chip and the first lead 210, the second lead 220, wherein one bonding wire is connected between the first lead 210 and the first contact pads 264, and another boding wire is connected between the second lead 220 and the second contact pad 266. The bonding wires 270a, 270b, for example, are made of Au, Al, Cu or other appropriate metals. Furthermore, through the bonding wire process, a protective layer (not labeled) can be disposed on the LED chip 260. The protective layer (not labeled), for example, is made of transparent gel materials, such as epoxy, silicone or ultraviolet gel.

According to the first embodiment of the invention, as the LED chip 260 is directly disposed on the heat dissipater 230, the heat generated by the LED chip 260 can be directly dissipated via the heat dissipater 230. Therefore, the LED chip 260 is not easy to be overheated and damaged even driven by a high current.

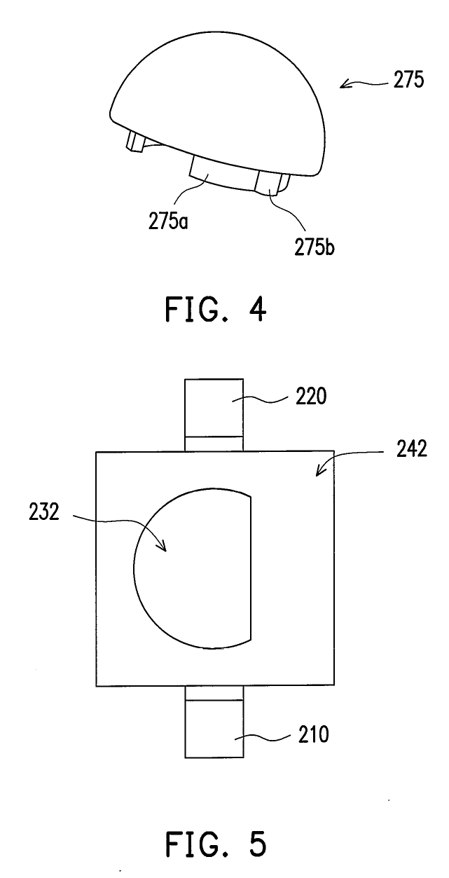

Referring to FIGS. 2 and 4, FIG. 4 is a perspective view for illustrating a lens of the LED package. The LED package 200 of the first embodiment, for example, further comprises a lens 275, disposed on the upper surface 242 of the housing 240, covering the LED chip 260. The upper surface 242 of the housing 240, for example, comprises at least a slot 242a and the lens 275, for example, comprises an engaging portion 275a for being adapted to be engaged the slot 242a. Additionally, the upper surface 242 of the housing 240 comprises a positioning slot 242b adjacent to the slot 242a, and the lens 275 for example further comprises a positioning protrusion 275b disposed on the engaging portion 275a for being engaged into the positioning slot 242b. The lens 275, for example, is made of polycarbonate (PC), polymethyl methacrylate PMMA, silicone, or epoxy.

As the housing 240 has the slot 242a and the positioning slot 242b, the lens 275 and the housing 240 are easily assembled. The positioning slot 242b and the positioning protrusion 275b match each other for preventing the lens 275 from rotating or shifting. Moreover, a glue is advantageously previously distributed in the slot 242a and the positioning slot 242b for solidly sticking the lens 275 and the housing 240 in the subsequent assembly process.

Referring to FIGS. 2 and 5, FIG. 5 is a schematic view of the lower surface of the LED package of FIG. 2. According to the LED package 200 of the first embodiment, the housing 240 has a lower surface 244 opposite to the upper surface 242, exposing a surface 232 of the heat dissipater 230, the surface 232 having a profile of round shape having a side cut for preventing the heat dissipater from rotating.

### THE SECOND EMBODIMENT

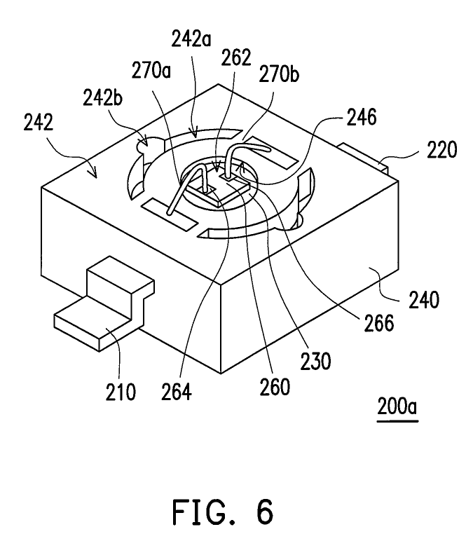

Referring to FIG. 6, FIG. 6 is a perspective view of an LED package according to the second embodiment of the invention. According to the second embodiment of the invention, the LED package 200a is similar with the LED package 200 of the first embodiment. The difference between the first and the second embodiments is that in the LED package 200a, the housing 240 has a recess 246 configured on the upper surface 242 of the housing 240. The recess 246 is adapted for receiving and exposing the heat dissipater 230. The LED chip 260 is disposed on the heat dissipater 230. The recess 246 can also be adapted for converging light emitted by the LED chip 260 for improving the light emitting efficiency.

### THE THIRD EMBODIMENT

According to both the first embodiment and the second embodiment, both of the first contact pad 264 and the second contact pad 266 of the LED chip 260 are disposed on the first surface 262. Such an LED chip can be either a blue light LED chip or a green light LED chip. However, other type of LED chips, for example red light LED chips, may have the first contact pad 264 and the second contact pad 266 respectively disposed on the first surface and the second surface thereof. LED packages adapted for using in such a type are to be illustrated below.

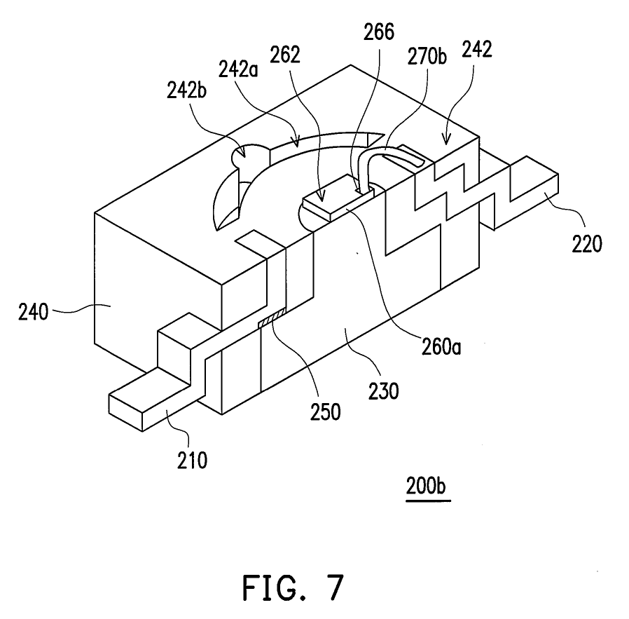

FIG. 7 is a perspective view of an LED package according to the third embodiment of the invention. Referring to FIG. 7, in the LED package 200b of the third embodiment, the first contact pad (not labeled) and the second contact pad 266 of the LED chip 260a are respectively disposed on a second surface (not labeled) and a first surface 262, which are opposite each other. The second contact pad 266 is electrically connected to the second lead 220, for example, via a bonding wire 270b. The first contact pad (not labeled) contacts the heat dissipater 230, and is electrically connected to the first lead 210 via the heat dissipater 230 and a conductor 250. The conductor 250, for example, can be, but not is limited to, silver gel.

As the present invention employs a conductor 250 connected between the heat dissipater 230 and the first lead 210, the first contact pad is electrically connected to the first lead 210 via the bonding wire when disposed on the first surface 262, and the first contact pad is electrically connected to the first lead 210 via the heat dissipater 230 and the conductor 250 when disposed on the second surface. Therefore, the LED package according to the present invention is adapted for using the red light LED chips, the green light LED chips or the blue light LED chips.

### THE FOURTH EMBODIMENT

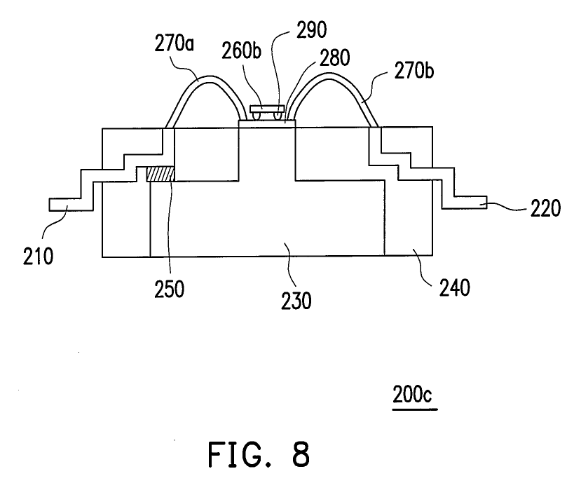

FIG. 8 is a cross sectional view of an LED package according to the fourth embodiment of the invention. Referring to FIG. 8, the LED package 200c according to the fourth embodiment of the invention employs a flip chip bonding method. The LED chip 260b is disposed on a submount 280, by which the LED chip 260b is electrically connected to the first lead 210 and the second lead 220. The submount 280 is electrically connected to the first lead 210 by the bonding wire 270a disposed between the submount 280 and the first lead 210, and is electrically connected to the second lead 220 by another bonding wire 270b disposed between the submount 280 and the second lead 220. The LED chip 260b is electrically connected to the submount 280, for example, via a protrusion 290. The submount 280 for example is made of AlN or silicon.

In summary, the LED package according to the present invention has at least the following advantages:
1. The present invention employs a conductor connected between the heat dissipater and the first lead. If the first contact pad is disposed on the second surface, it is electrically connected to the first lead via the heat dissipater and the conductor. Therefore, the LED package according to the present invention is adapted for using red light LED chips, green light LED chips or blue light LED chips;
2. The LED chip is directly disposed on the heat dissipater, thus the heat generated by the LED chip can be directly dissipated via the heat dissipater. Therefore, the LED chip is not easy to be overheated and damaged.

Other modifications and adaptations of the above-described preferred embodiments of the present invention may be made to meet particular requirements. This disclosure is intended to exemplify the invention without limiting its scope. All modifications that incorporate the invention disclosed in the preferred embodiment are to be construed as coming within the scope of the appended claims or the range of equivalents to which the claims are entitled.

What is claimed is:

1. A light emitting diode (LED) package, comprising:
a first lead;
a second lead;
a heat dissipater, disposed between the first lead and the second lead;
a housing, covering the heat dissipater and parts of the first lead and the second lead, wherein the housing has an upper surface for exposing the heat dissipater, the first lead, and the second lead;
a conductor, connected between the first lead and the heat dissipater; and
an LED chip, having a first surface and a second surface opposite to the first surface, wherein the second surface is disposed on the heat dissipater and the LED chip is electrically connected to the first lead and the second lead.

2. The LED package according to claim 1, further comprises a first contact pad and a second contact pad, disposed on the first surface of the LED chip, the LED chip being electrically connected to the first lead and the second lead respectively via the first contact pad and the second contact pad.

3. The LED package according to claim 2, further comprising two bonding wires, both of which are respectively connected between the first lead and the first contact pads, and between the second lead and the second contact pad.

4. The LED package according to claim 1, wherein the LED chip comprises a first contact pad and a second contact pad, respectively disposed on the second surface and the first surface of the LED chip, the LED chip being electrically connected to the first lead and the second lead respectively via the first contact pad and the second contact pad.

5. The LED package according to claim 4 further comprising a bonding wire, connected between the second contact pad and the second lead.

6. The LED package according to claim 1 further comprising a submount, disposed between the LED chip and the heat dissipater, whereby the LED chip is electrically connected to the first lead and the second lead via the submount.

7. The LED package according to claim 6, further comprising a plurality of protrusions, connected between the LED chip and the submount.

8. The LED package according to claim 7, further comprising two bonding wires, both of which are respectively connected between the submount and the first lead, and between the submount and the second lead.

9. The LED package according to claim 1, wherein the conductor is silver gel.

10. The LED package according to claim 1, wherein the housing has a recess disposed on the first surface for exposing the heat dissipater, and the LED chip is disposed on the heat dissipater in the recess.

11. The LED package according to claim 1, wherein the heat dissipater is a heat sink.

12. The LED package according to claim 1, wherein the heat dissipater comprises:
a heat sink, and
a heat spread plate, disposed between the heat sink and the LED chip.

13. The LED package according to claim 1, further comprising a lens, disposed on the upper surface of the housing and covering the LED chip.

14. The LED package according to claim 13, wherein the upper surface of the housing comprises a slot and the lens comprises an engaging portion for being engaged into the slot.

15. The LED package according to claim 14, wherein the upper surface of the housing comprises a positioning slot adjacent to the slot, and the lens comprises a positioning protrusion disposed on the engaging portion for being engaged into the positioning slot.

16. The LED package according to claim 1, wherein the housing comprises a lower surface opposite to the upper surface, exposing a surface of the heat dissipater, the surface having a profile of round shape with a side cut.

17. The LED package according to claim 1, further comprising a protection layer, disposed on the LED chip.
